(19) United States
(12) Patent Application Publication
(10) Pub. No.: US 2014/0001471 A1
(43) Pub. Date: Jan. 2, 2014

(54) CONFORMAL SHIELDING MODULE

(71) Applicant: Kuan-Hsing LI, Taichung City (TW)

(72) Inventor: Kuan-Hsing LI, Taichung City (TW)

(73) Assignees: UNIVERSAL GLOBAL SCIENTIFIC INDUSTRIAL CO., LTD., CAOTUN TOWNSHIP (TW); UNIVERSAL SCIENTIFIC INDUSTRIAL CO., LTD., SHANGHAI CITY (CN)

(21) Appl. No.: 13/538,160

(22) Filed: Jun. 29, 2012

(51) Int. Cl. H01L 23/482; H01L 23/552

(52) U.S. Cl. 257/48; 257/659; 257/E23.114; 257/E23.012

(57) ABSTRACT

A conformal shielding module comprising a substrate, at least one electronic component mounted on the substrate, and a molding compound covering the electronic component. The molding compound includes a vertical channel extending from a surface of the molding component to the electronic component, and an electrically conductive structure formed inside the vertical channel. The electrically conductive structure is electrically connected to the electronic component and includes a testing contact on the surface of the molding compound for in-circuit test of the electronic component.

### BACKGROUND OF THE INVENTION

1. Field of the Invention

The present invention relates generally to a conformal shielding module, and more particularly to a conformal shielding module which can allow an in-circuit test to be performed on internal electronic components.

2. Description of the Related Art

Referring to FIG. 1, during the packaging process of a conventional conformal shielding module 1, an electromagnetically shielding layer 3 is formed on the surface of a molding compound 2 by metal sputtering, spray coating, or another coating manner instead of the conventional metal cover for lower production cost. After the packaging process, a tester can apply in-circuit test to the packaging module by a testing probe to confirm whether its functions are normally or not.

However, in the conventional design, all of the electronic components 4 are sealed by the molding compound 2, so the electronic components 4 inside the molding compound 2 cannot be tested separately. When the tester tests and finds there is something wrong within the packaging module, the tester must destroy the packaging module 1, before conducting damage analysis, to identify the problem. Thus, the conventional conformal shielding module 1 indeed needs improvement in structure.

### SUMMARY OF THE INVENTION

The primary objective of the present invention is to provide a conformal shielding module which can allow an in-circuit test to be performed on internal electronic components without removal of the molding compound.

The foregoing objective of the present invention is attained by the conformal shielding module comprising a substrate, at least one electronic component, a molding compound, and an electrically conductive structure. The at least one electronic component is mounted to a surface of the substrate. The molding compound is perfused on the surface of the substrate to cover the at least one electronic component for protecting the at least one electronic component. A vertical channel is formed inside the molding compound to run therethrough, extending to the at least one electronic component from a surface of the molding compound. The electrically conductive structure is disposed to the vertical channel and electrically connected with the at least one electronic component to form a testing contact on the surface of the molding compound in such a way that the tester can conveniently apply in-circuit test to the at least one electronic component via the testing contact.

In the conformal shielding module of the present invention, an electromagnetically shielding layer can be disposed on the surface of the molding compound for providing electromagnetic shielding effect. Besides, the molding compound includes a concavity formed on the surface thereof and communicating with the vertical channel. The testing contact of the electrically conductive structure is formed inside the concavity for avoiding short circuit with the electromagnetically shielding layer.

### BRIEF DESCRIPTION OF THE DRAWINGS

FIG. 1 is a sectional view of a conventional conformal shielding module.

FIG. 2 is a sectional view of a first preferred embodiment of the present invention.

FIG. 3 is a sectional view of a second preferred embodiment of the present invention, illustrating that an electromagnetically shielding layer is disposed on a surface of a molding compound.

FIG. 4 is a sectional view of a third preferred embodiment of the present invention.

FIG. 5 similar to FIG. 4 illustrates that the electromagnetically shielding layer is disposed on the surface of the molding compound.

FIG. 6 is another sectional view of the third preferred embodiment of the present invention, illustrating that a concavity is differently shaped.

FIG. 7 similar to FIG. 6 illustrates that the electromagnetically shielding layer is disposed on the surface of the molding compound.

FIG. 8 is a sectional view of a stacked package to which a third preferred embodiment of the present invention is applied.

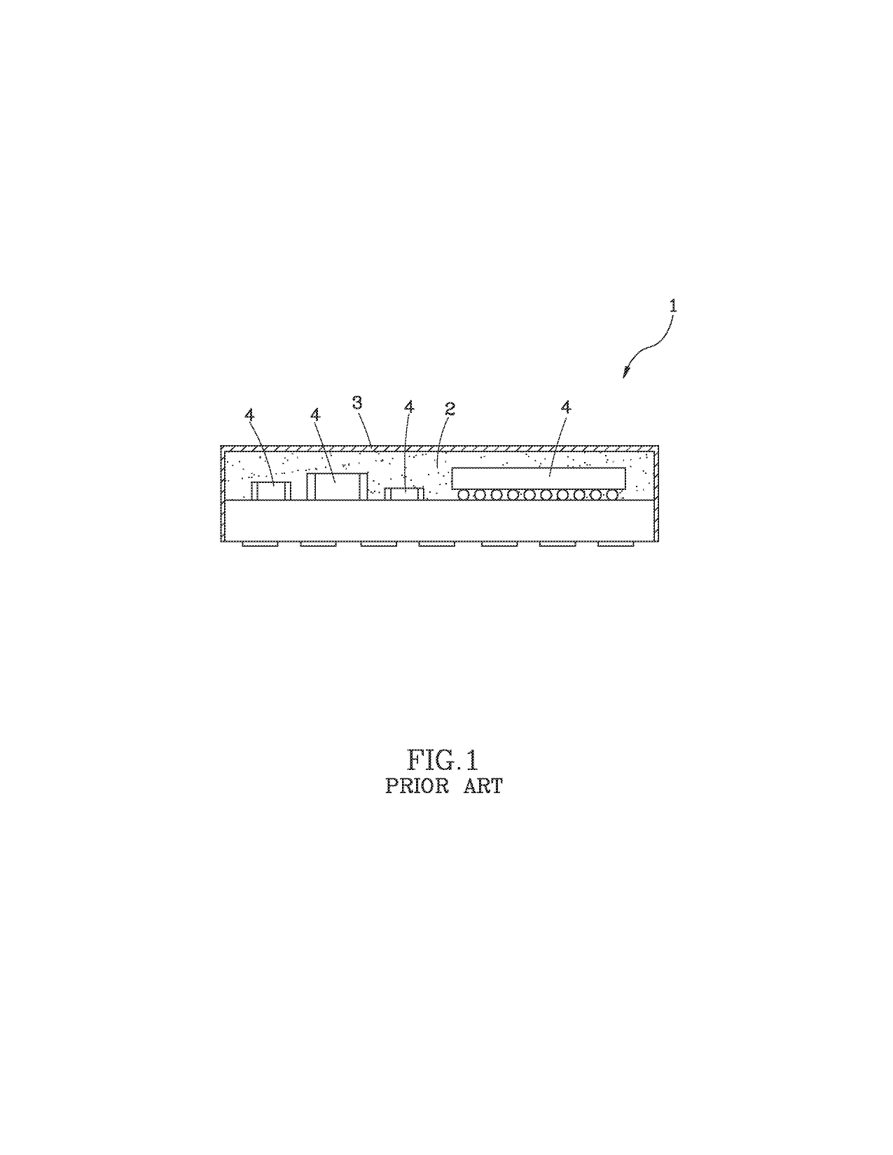

### DETAILED DESCRIPTION OF PREFERRED EMBODIMENTS

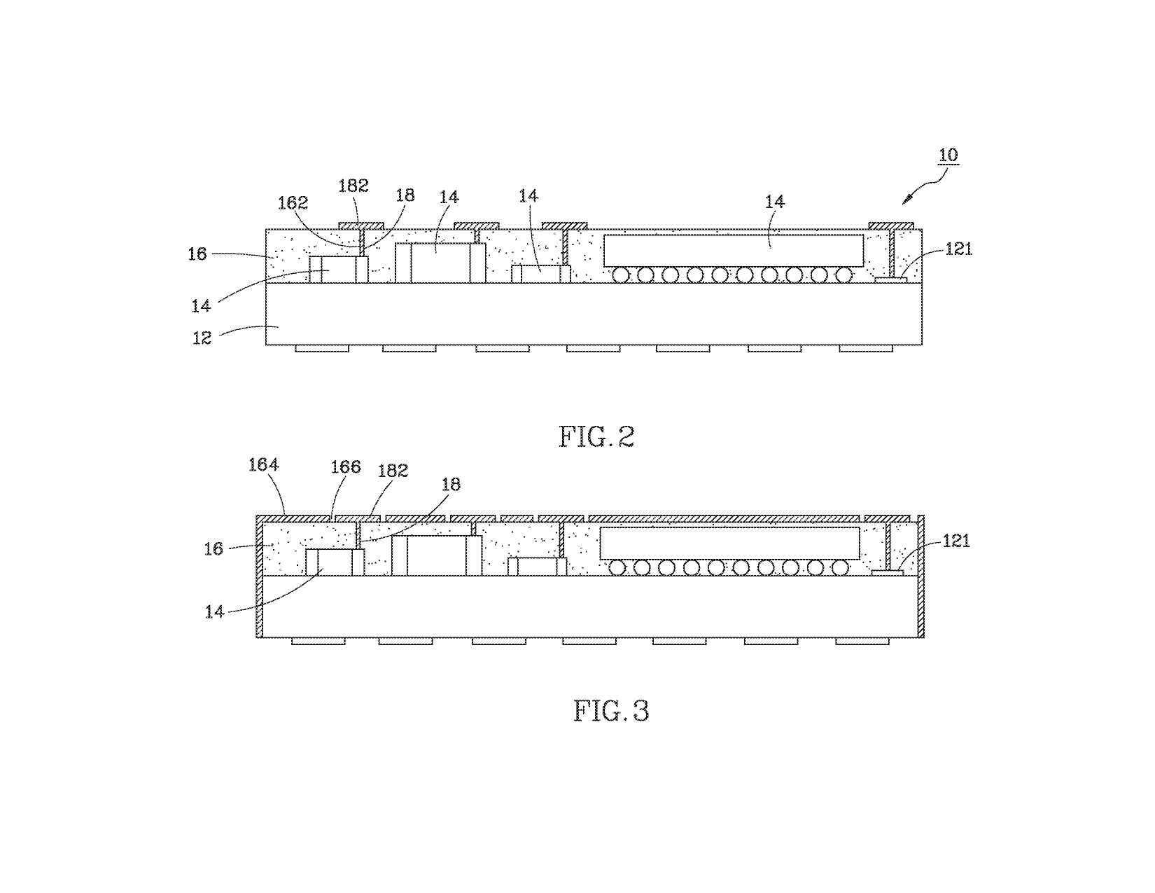

Referring to FIG. 2, a conformal shielding module 10 comprising a substrate 12, at least one electronic component 14, a molding compound 16, and at least one electrically conductive structure 18. The electronic component 14 and the electrically conductive structure 18 are plural in number in a first preferred embodiment of the present invention. The detailed descriptions and operations of these elements as well as their interrelations are recited in the respective paragraphs as follows.

The substrate 12 is structurally identical to that of the conventional multi-layer printed circuit board. All of the electronic components 14 are mounted to a surface of the substrate 12 to be electrically connected with the substrate 12. At least one testing point 121 can be additionally mounted on the surface of the substrate 12 where this surface faces the molding compound 16.

The molding compound 16 is perfused on the surface of the substrate 12 to cover the electronic components 14 for protecting the electronic components 14. A plurality of vertical channels 162 are formed inside the molding compound 16 by laser scribing or chemical etching according to the number of the electronic components 14 to be tested, each extending to the electronic component 14 or to the testing point 121 from the surface of the molding compound 16.

The electrically conductive structure 18 is provided with a mask (not shown) having a predetermined pattern formed thereon by means of metal sputtering, spray coating, or another coating manner and disposed inside the vertical channels 162 of the molding compound 16. In this way, one end of the electrically conductive structure 18 is electrically connected with the electronic components 14 to be tested or with the testing point 121 and the other end defines a testing contact 182 on the surface of the molding compound 16 for a testing probe (not shown) to contact.

When the tester intends to conduct a damage analysis, the tester only needs to make the testing probe contact the testing contact 182 and then basic in-circuit test can be applied to the electronic components 14 or the testing point 121 to be tested. And meanwhile, the tester can be aware of which of the electronic components 14 is problematic or identify whether the substrate 12 functions normally or not. Thus, it will not be necessary to remove the molding compound 16 or destroy the whole module and the prior art can be effectively improved.

It is to be noted that the electronic components 14 to be tested are not limited to those indicated in the first embodiment of the present invention but some or all of the electronic components 14; besides, the substrate 12 can optionally exclude any testing point 121 thereon according to the actual requirement of the technician in the art.

Referring to FIG. 3, in a second preferred embodiment of the present invention, an electromagnetic shielding layer 164 can be disposed on the surface of the molding compound 16 by metal sputtering, spray coating, or other coating manner for providing the electronic components 14 with electromagnetic shielding effect. The electrically conductive structure 18 provided with a mask having a predetermined pattern is completed by the same manufacturing process as that of the electromagnetic shielding layer 164. However, to prevent the electromagnetic shielding layer 164 and the testing contact 182 from short circuit, a gap 166 must be formed between them.

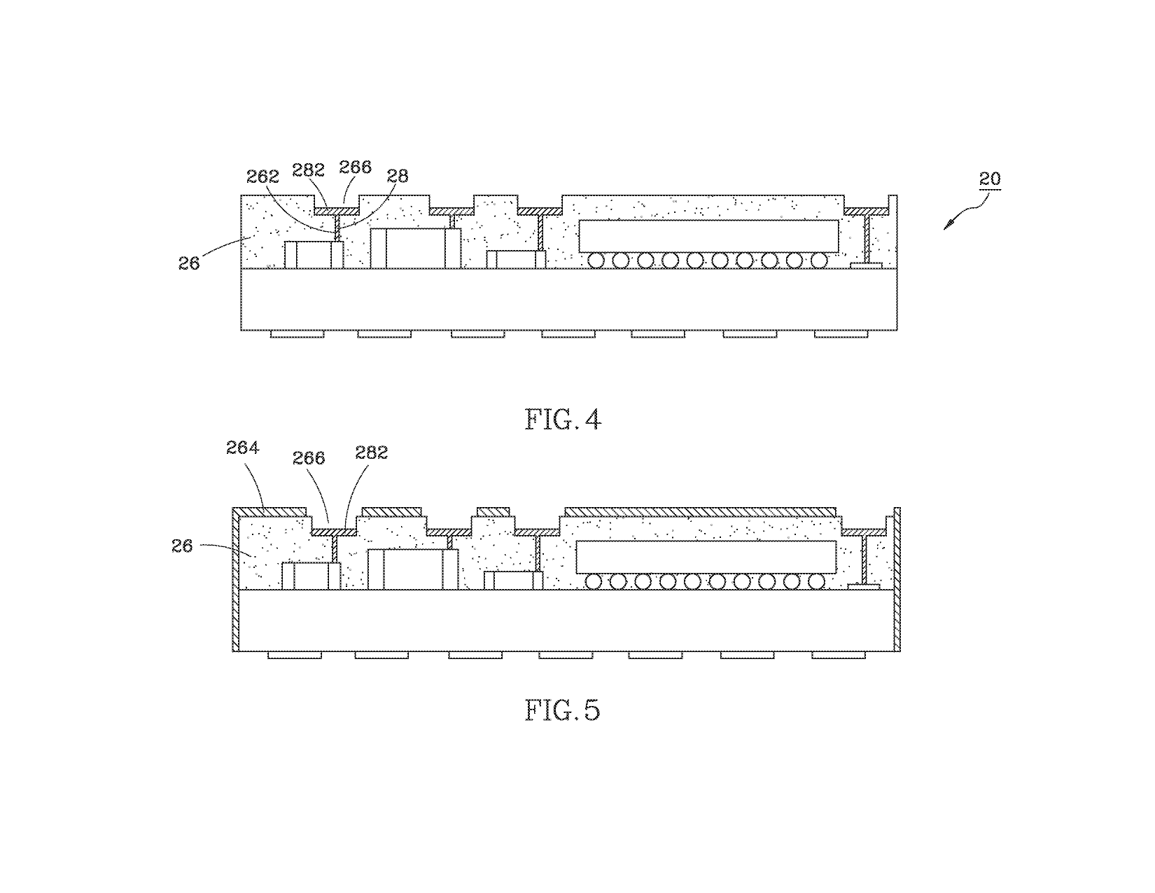

Referring to FIGS. 4-5, a conformal shielding module 20 of a third preferred embodiment of the present invention is similar to that of the aforesaid embodiment, having the following difference. Concavities 266 each having a rectangular section are formed on the surface of the molding compound 26, corresponding to the vertical channels 262 separately in such a way that a testing contact 282 located on a top end of the electrically conductive structure 28 is formed inside each of the concavities 266. Spaced by the concavities 266, when the electrically conductive shielding layer 264 is disposed on a position other than the concavities 266, the electrically conductive shielding layer 264 and the testing contact 282 can avoid short circuit therebetween.

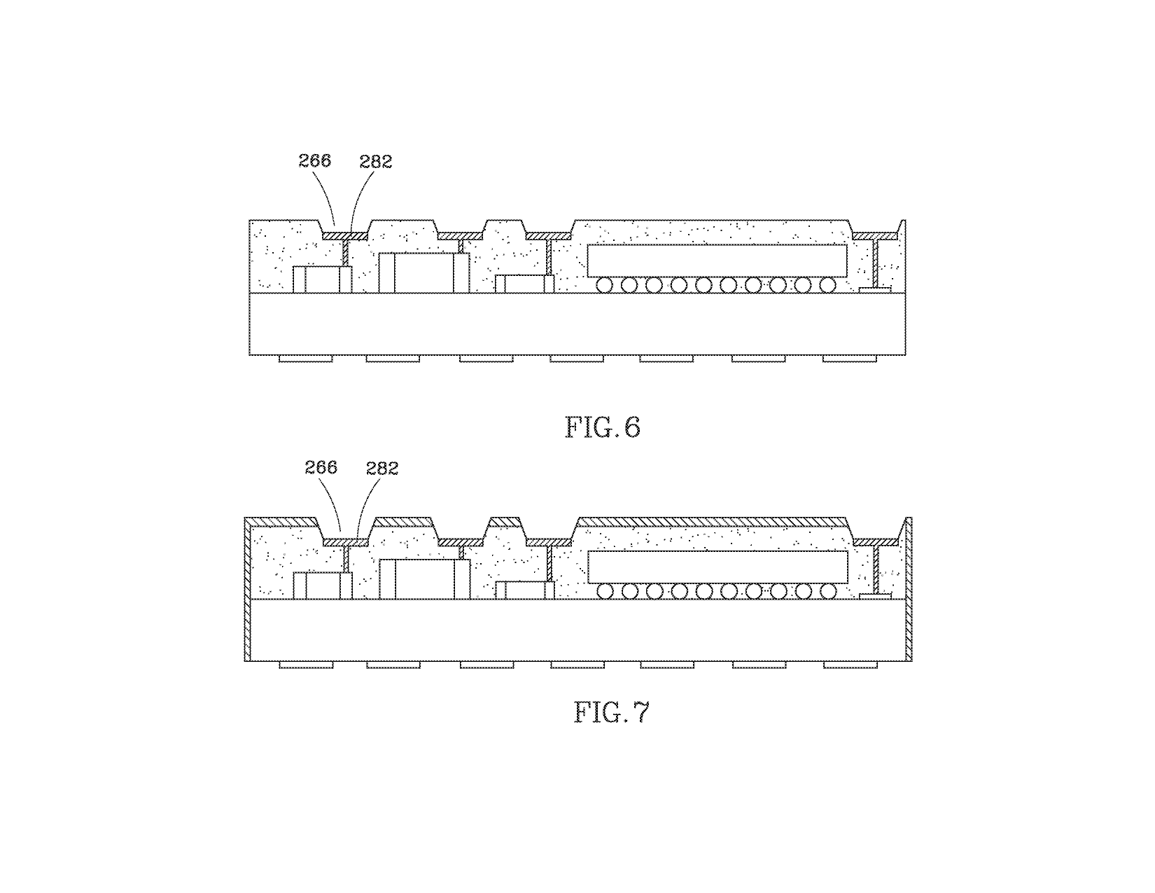

The section of the concavity 266 is not limited to a rectangle in shape but can be a trapezoid in which a top side (open) thereof is bigger than a bottom side thereof, as shown in FIGS. 6-7, to facilitate the testing probe to extend into the concavity 266 for contact with the testing contact 282.

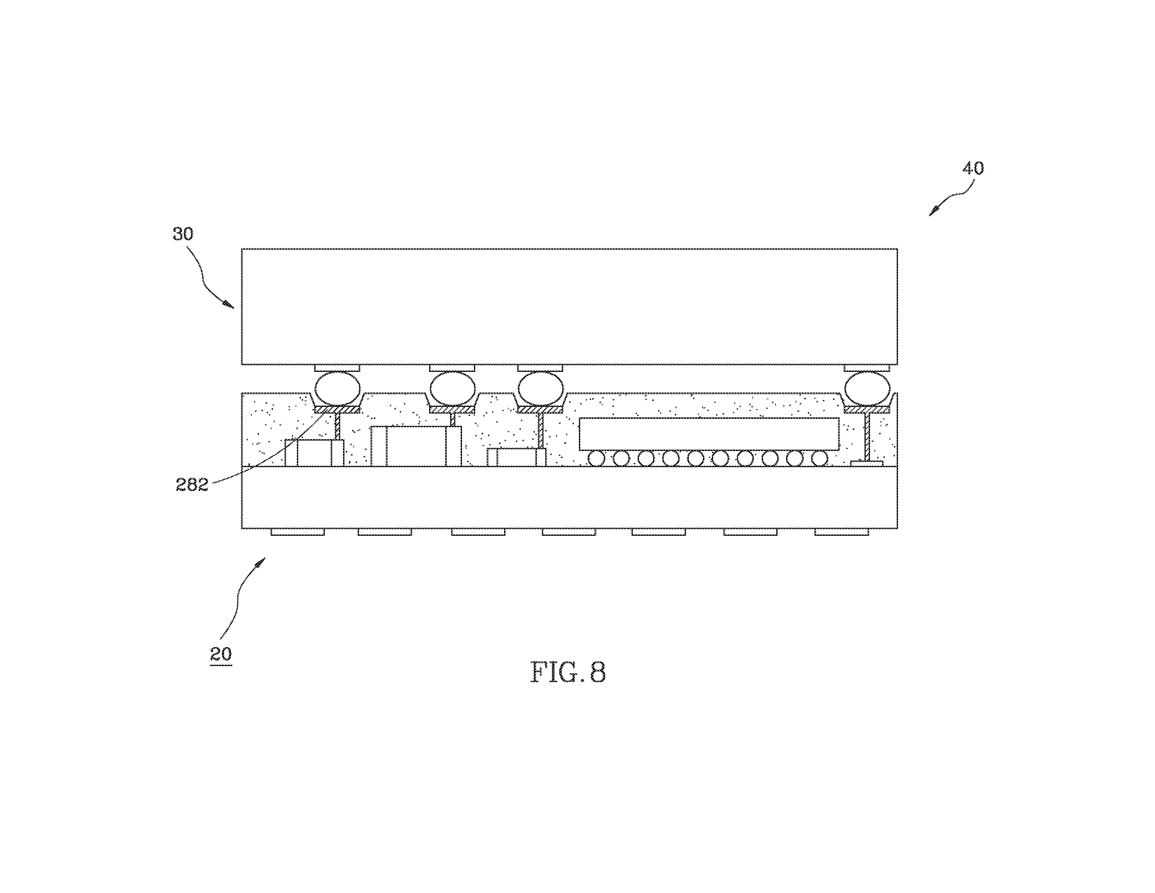

It is to be noted that the conformal shielding module 20 of this embodiment can employ the testing contacts 282 and one semiconductor device 30 stacked on a top side of the conformal shielding module 20 for electric connection to further constitute a stacked package 40, as shown in FIG. 8.

In light of the vertical channels and the electrically conductive structure of the conformal shielding module of the present invention, the in-circuit test of the electronic components can be quickly finished without removal of the molding compound and whatever the problem happens can be easily located to effectively enhance the efficiency of the packaging process.

Although the present invention has been described with respect to specific preferred embodiments thereof, it is in no way limited to the specifics of the illustrated structures but changes and modifications may be made within the scope of the appended claims.

1. A conformal shielding module comprising:
a substrate which comprises at least one testing point, wherein said at least one testing point is configured to test whether the substrate is functioning properly;
a plurality of electronic components mounted to a surface of the substrate;
a molding compound perfused to the surface of the substrate and covering the plurality of electronic components and the at least one testing point, a plurality of vertical channels running through the molding compound and extending to every electronic component of the plurality of electronic components and the at least one testing point from the surface of the molding compound; and
a plurality of electrically conductive structures electrically connected with every electronic component and the at least one testing point through respective vertical channels and defining a plurality of testing contacts on the surface of the molding compound.

2. The conformal shielding module as defined in claim 1, wherein the molding compound further comprises an electromagnetic shielding layer disposed on the surface thereof, a gap being formed between the electromagnetic shielding layer and the testing contact of the electrically conductive structure.

3. The conformal shielding module as defined in claim 1, wherein the molding compound further comprises at least one concavity formed on the surface thereon and communicating with the at least one vertical channel; the testing contact is located on a top end of the electrically conductive structure and in the at least one concavity.

4. The conformal shielding module as defined in claim 3, wherein a section of the at least one concavity is rectangle in shape.

5. The conformal shielding module as defined in claim 3, wherein a section of the concavity is trapezoid in shape, in which a top side thereof is bigger than a bottom side thereof.

6. The conformal shielding module as defined in claim 3, wherein the molding compound further comprises an electromagnetic shielding layer disposed on the surface other than the concavity.

7. The conformal shielding module as defined in claim 1, wherein the electrically conductive structure is completed in the same manufacturing process as that of the electromagnetic layer.

8. The conformal shielding module as defined in claim 2, wherein the electrically conductive structure is made by the same manufacturing process as that of the electromagnetic layer.

9. The conformal shielding module as defined in claim 6, wherein the electrically conductive structure is made by the same manufacturing process as that of the electromagnetic layer.

10. (canceled)

11. The conformal shielding module as defined in claim 1 further comprising a semiconductor device, which is stacked on a top side of the conformal shielding module, wherein the conformal shielding module is electrically connected with the semiconductor device via the testing contact to constitute a stacked package.
